(19) United States
(12) Patent Application Publication
(10) Pub. No.: US 2014/0048013 A1
(43) Pub. Date: Feb. 20, 2014

(54) SEED LAYER FOR ZnO AND DOPED-ZnO THIN FILM NUCLEATION AND METHODS OF SEED LAYER DEPOSITION

(71) Applicants: Guowen Ding, San Jose, CA (US); Hien Minh Huu Le, San Jose, CA (US); Zhi-Wen Sun, Sunnyvale, CA (US)

(72) Inventors: Guowen Ding, San Jose, CA (US); Mohd Fadzli Anwar Hassan, San Francisco, CA (US); Hien Minh Huu Le, San Jose, CA (US); Zhi-Wen Sun, Sunnyvale, CA (US)

(73) Assignee: Intermolecular, Inc., San Jose, CA (US)

(21) Appl. No.: 13/588,764

(22) Filed: Aug. 17, 2012

(51) Int. Cl. C30B 25/06; C30B 23/02; C30B 25/02; C30B 19/00

(52) U.S. Cl. 117/58; 117/106; 117/95

(57) ABSTRACT

Zinc oxide layer, including pure zinc oxide and doped zinc oxide, can be deposited with preferred crystal orientation and improved electrical conductivity by employing a seed layer comprising a metallic element. By selecting metallic elements that can easily crystallized at low temperature on glass substrates, together with possessing preferred crystal orientations and sizes, zinc oxide layer with preferred crystal orientation and large grain size can be formed, leading to potential optimization of transparent conductive oxide layer stacks.

### FIELD OF THE INVENTION

The present invention relates to low emissivity panels, and more particularly to low-e panels having a seed layer to improved ZnO or doped ZnO crystallization and methods for forming such low-e panels.

### BACKGROUND OF THE INVENTION

Sunlight control glasses are commonly used in applications such as building glass windows and vehicle windows, typically offering high visible transmission and low emissivity. High visible transmission can allow more sunlight to pass through the glass windows, thus being desirable in many window applications. Low emissivity can block infrared (IR) radiation to reduce undesirable interior heating.

In low emissivity glasses, IR radiation is mostly reflected with minimum absorption and emission, thus reducing the heat transferring to and from the low emissivity surface. Typical sunlight control glasses have generally an emissivity of about 0.1 and a light transmission of about 80%. High transmittance, low emissivity glasses generally include a reflective metal film (e.g., silver) to provide infrared reflectance and low emissivity, along with various dielectric layers, such as tin oxide or zinc oxide, to provide a barrier to prevent oxidation or corrosion, as well as to act as optical fillers and function as anti-reflective coating layers to improve the optical characteristics of the glass panel.

The overall quality of the reflective layer, for example, its crystallographic orientation, is important for achieving the desired performance, such as high visible light transmission and low emissivity (i.e., high heat reflection). One known method to achieve low emissivity is to form a relatively thick silver layer. However, as the thickness of the silver layer increases, the visible light transmission of the reflective layer is reduced, as is manufacturing throughput, while overall manufacturing costs are increased. Therefore, is it desirable to form the silver layer as thin as possible, while still providing emissivity that is suitable for low-e applications.

### SUMMARY OF THE DESCRIPTION

The present invention relates to methods for forming a zinc oxide containing layer to have large grain size with preferred crystal orientation. In some embodiments, the present invention discloses methods to promote (002) oriented zinc oxide layer on glass substrates for low emissivity glass applications. The (002) oriented zinc oxide can enhance the conductivity of a silver layer deposited thereon, by achieving preferred (111) crystal orientation. In some embodiments, the enhanced zinc oxide layer can lead to improved electron mobility and electrical conductivity, providing better conductive films at a same optical transparency level.

In some embodiments, the present invention discloses forming a seed layer comprising a metallic element before forming the zinc oxide layer. Metallic elements have strong tendency to crystallize at low temperature, even on amorphous substrates, thus a seed layer containing metallic elements can have a preferred crystal orientation, which can serve to promote the formation of a zinc oxide layer with a desired crystalline structure. For example, metallic seed layers having metals possessing hexagonal close packing (hcp) and face center cubic (fcc) (111) structure can induce pseudo-epitaxial growth of basal plane (002) of zinc oxide on top of the metallic seed layer.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1A illustrates an exemplary thin film coating according to some embodiments of the present invention.

FIG. 1B illustrates a low emissivity transparent panel 105 according to some embodiments of the present invention.

FIG. 2 illustrates exemplary physical vapor deposition (PVD) systems according to some embodiments of the present invention.

FIG. 3 illustrates an exemplary in-line deposition system according to some embodiments of the present invention.

FIG. 4 illustrates an exemplary flow chart for seed layer deposition according to some embodiments of the present invention.

FIG. 5 illustrates another exemplary flow chart for seed layer deposition according to some embodiments of the present invention.

### DETAILED DESCRIPTION OF THE PREFERRED EMBODIMENTS

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

In some embodiments, the present invention discloses methods, and coated panels fabricated from the methods, for forming a low-e panel with improved overall quality of an infrared reflective layer (such as silver, gold or copper), comprising forming a seed layer for a zinc oxide or doped zinc oxide layer, which then can be used as a seed layer for the infrared reflective layer.

Generally, it is preferable to form the infrared reflective layer in such a way that visible light transmission is high and emissivity is low. It is also preferable to maximize volume production, throughput, and efficiency of the manufacturing process used to form low-e panels.

For example, with an infrared reflective layer comprising silver, it is preferably for the silver layer to have (111) crystallographic orientation because it allows for the silver layer to have relatively high electrical conductivity, and thus relatively low sheet resistance (Rs) at thin layer thickness. Thin layer thickness is desirable to provide high visible light transmission, and low sheet resistance is preferred low sheet resistance can offer low infrared emissivity.

To promote the crystal orientation of the infrared reflective layer, a seed layer can be used. Generally, seed layers are relatively thin layers of materials formed on a surface (e.g., a substrate) to promote a particular characteristic of a subsequent layer formed over the surface (e.g., on the seed layer). For example, seed layers may be used to improve adhesion between the subsequent layer and the substrate or increase the rate at which the subsequent layer is grown on the substrate during the respective deposition process.

A seed layer can also affect the crystalline structure (or crystallographic orientation) of the subsequent layer, which is sometimes referred to as “templating.” For example, the interaction of the material of the subsequent layer with the crystalline structure of the seed layer causes the crystalline structure of the subsequent layer to be formed in a particular orientation.

For example, a seed layer can be used to promote growth of the infrared reflective layer in a particular crystallographic orientation. For example, a seed layer can comprise a material with a hexagonal crystal structure and can be formed with a (002) crystallographic orientation (such as zinc oxide or doped zinc oxide), which promotes growth of a silver layer in the (111) orientation when the silver layer has a face centered cubic crystal. Thus the seed layer can improve the conductivity of the deposited silver layer such that the thickness of the silver layer may be reduced while still providing the desirably low emissivity. In some embodiments, the formation of a high conductivity and thin silver layer can be achieved by forming a relatively thin (e.g., up to about 5 nm) seed layer of, for example, zinc oxide or doped zinc oxide on the substrate, before depositing the silver layer.

In some embodiments, the crystallography orientation can be characterized by X-ray diffraction (XRD) technique, which is based on observing the scattered intensity of an X-ray beam hitting the layer, e.g., silver layer or seed layer, as a function of the X-ray characteristics, such as the incident and scattered angles. For example, zinc oxide seed layer can show a pronounced (002) peak and higher orders in a θ−2θ diffraction pattern. This suggests that zinc oxide crystallites with the respective planes oriented parallel to the substrate surface are present.

In some embodiments, the terms “silver layer having (111) crystallography orientation”, or “zinc oxide seed layer having (002) crystallography orientation” comprise a meaning that there is a (111) preferred crystallographic orientation for the silver layer or a (002) preferred crystallographic orientation for the zinc oxide seed layer, respectively. The preferred crystallographic orientation can be determined, for example, by observing pronounced crystallography peaks in an XRD characterization.

In some embodiments, the present invention discloses methods, and coated panels formed for the methods, to improve a zinc oxide containing seed layer, which in turn, can improve an infrared reflective layer, e.g., a silver layer. In some embodiments, the present invention discloses methods to form zinc oxide or doped zinc oxide layers having large grain sizes with preferred crystal orientation. For example, (002) oriented zinc oxide or doped zinc oxide layers can be formed on glass substrates to enhance the conductivity of a subsequently deposited silver layer.

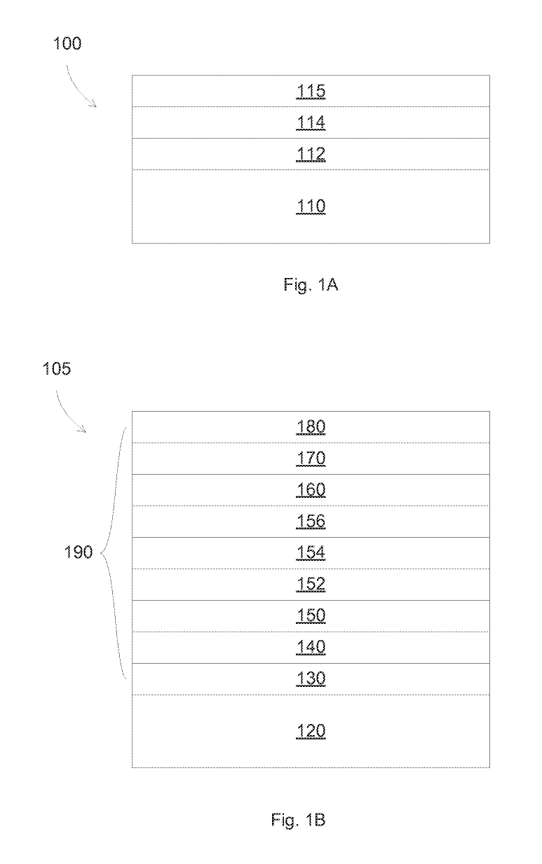

FIG. 1A illustrates an exemplary thin film coating according to some embodiments of the present invention. An infrared reflective layer, such as a silver layer 115, is disposed on a second seed layer, such as a zinc oxide or a doped zinc oxide layer 114, which is disposed on a first seed layer 112 on a substrate 110 to form a coated transparent panel 100, which has high visible light transmission, and low IR emission. The second seed layer 114 preferably comprises (002) crystal orientation to promote a (111) crystal orientation of the silver layer 115. The first seed layer 112 preferably comprises materials and/or crystal orientation to promote the (002) crystal orientation of the zinc oxide or doped zinc oxide layer 114. The dopants for doped zinc oxide can comprise aluminum, magnesium, or tin. Other dopants can also be used.

The layers 112, 114, and/or 115 can be sputtered deposited using different processes and equipment, for example, the targets can be sputtered under direct current (DC), pulsed DC, alternate current (AC), radio frequency (RF) or any other suitable conditions. In some embodiments, the present invention discloses a physical vapor deposition method for depositing the layers 112, 114, and/or 115. The deposition process can comprise a gas mixture introduced to a plasma ambient to sputtering material from one or more targets disposed in the processing chamber. The sputtering process can further comprise other components such as magnets for confining the plasma, and utilize different process conditions such as DC, AC, RF, or pulse sputtering.

In some embodiments, the present invention discloses a coating stack, comprising multiple layers for different functional purposes. For example, the coating stack can comprise a first seed layer to facilitate the deposition of the reflective layer, a second seed layer to facilitate the deposition of the first seed layer, an oxygen diffusion barrier layer disposed on the reflective layer to prevent oxidation of the reflective layer, a protective layer disposed on the substrate to prevent physical or chemical abrasion, or an antireflective layer to reduce visible light reflection. The coating stack can comprise multiple layers of reflective layers to improve IR emissivity.

FIG. 1B illustrates a low emissivity transparent panel 105 according to some embodiments of the present invention. The low emissivity transparent panel can comprise a glass substrate 120 and a low-e stack 190 formed over the glass substrate 120. The glass substrate 120 in one embodiment is made of a glass, such as borosilicate glass, and has a thickness of, for example, between 1 and 10 millimeters (mm). The substrate 120 may be square or rectangular and about 0.5-2 meters (m) across. In some embodiments, the substrate 120 may be made of, for example, plastic or polycarbonate.

The low-e stack 190 includes a lower protective layer 130, a lower oxide layer 140, a first seed layer 150, a second seed layer 152, a reflective layer 154, a barrier layer 156, an upper oxide 160, an optical filler layer 170, and an upper protective layer 180. Some layers can be optional, and other layers can be added, such as interface layer or adhesion layer. Exemplary details as to the functionality provided by each of the layers 130-180 are provided below.

The various layers in the low-e stack 190 may be formed sequentially (i.e., from bottom to top) on the glass substrate 120 using a physical vapor deposition (PVD) and/or reactive (or plasma enhanced) sputtering processing tool. In one embodiment, the low-e stack 190 is formed over the entire glass substrate 120. However, in other embodiments, the low-e stack 190 may only be formed on isolated portions of the glass substrate 120.

The lower protective layer 130 is formed on the upper surface of the glass substrate 120. The lower protective layer 130 can comprise silicon nitride, silicon oxynitride, or other nitride material such as SiZrN, for example, to protect the other layers in the stack 190 from diffusion from the substrate 120 or to improve the haze reduction properties. In some embodiments, the lower protective layer 130 is made of silicon nitride and has a thickness of, for example, between about 10 nm to 50 nm, such as 25 nm.

The lower oxide layer 140 is formed on the lower protective layer 130 and over the glass substrate 120. The lower oxide layer 140 is preferably a metal oxide or metal alloy oxide layer and can serve as an antireflective layer.

The second seed layer 152 can be used to provide a seed layer for the IR reflective film, for example, a zinc oxide layer deposited before the deposition of a silver reflective layer can provide a silver layer with lower resistivity, which can improve its reflective characteristics. The second seed layer can comprise zinc oxide or doped zinc oxide.

In some embodiments, the second seed layer 152 can be continuous and covers the entire substrate. For example, the thickness of the second seed layer can be less than about 100 Angstroms, and preferably less than about 50 Angstroms. Alternatively, the second seed layer 152 may not be formed in a completely continuous manner. The second seed layer can be distributed across the substrate surface such that each of the second seed layer areas is laterally spaced apart from the other second seed layer areas across the substrate surface and do not completely cover the substrate surface. For example, the thickness of the second seed layer 152 can be a monolayer or less, such as between 2.0 and 4.0 Å, and the separation between the layer sections may be the result of forming such a thin seed layer (i.e., such a thin layer may not form a continuous layer).

The reflective layer 154 is formed on the second seed layer 152. The IR reflective layer can be a metallic, reflective film, such as gold, copper, or silver. In general, the IR reflective film comprises a good electrical conductor, blocking the passage of thermal energy. In some embodiments, the reflective layer 154 is made of silver and has a thickness of, for example, 100 Å. Because the reflective layer 154 is formed on the second seed layer 152, for example, due to the (002) crystallographic orientation of the second seed layer 152, growth of the silver reflective layer 154 in a (111) crystalline orientation is promoted, which offers low sheet resistance, leading to low panel emissivity.

Because of the promoted (111) texturing orientation of the reflective layer 154 caused by the second seed layer 152, the conductivity and emissivity of the reflective layer 154 is improved. As a result, a thinner reflective layer 154 may be formed that still provides sufficient reflective properties and visible light transmission. Additionally, the reduced thickness of the reflective layer 154 allows for less material to be used in each panel that is manufactured, thus improving manufacturing throughput and efficiency, increasing the usable life of the target (e.g., silver) used to form the reflective layer 154, and reducing overall manufacturing costs.

In some embodiments, the present invention discloses a first seed layer 150, serving as a seed layer for the second ZnO seed layer 152. The first seed layer 150 can further improve the ZnO film crystallinity and the preferred crystal orientation for the (002) basal plane to optimize the optical and electrical properties of the second ZnO seed layer 152. In some embodiments, the present invention discloses methods to improve the second seed layer (e.g., the seed layer for the infrared reflective layer) by providing a nucleation layer, e.g. a first seed layer to promote the film crystallinity and the crystal orientation of the second seed layer.

In some embodiments, the first seed layer can comprise materials that can be easily crystallized, such as metal materials or materials having tendency to crystallize at low temperatures. The first seed layer can also preferably form hexagonal close packing (hcp) or face center cubic (fcc) (111) structure. The first seed layer can preferably be oxidizable to form oxides with high index of refraction.

In some embodiments, the first seed layer can have similar characteristics as those of the second seed layer. For example, the first seed layer can be continuous and covers the entire substrate, with thickness less than about 10 nm or less than about 5 nm. Alternatively, the first seed layer may not be formed in a completely continuous manner. The thickness of the first seed layer can be a monolayer or less, such as between 0.2 and 0.4 nm.

Because of the promoted (111) crystal orientation of the reflective layer 154, which is caused by the promoted (002) crystal orientation of the second seed layer 152, which, in turn, is caused by the first seed layer 150, the conductivity and emissivity of the reflective layer 154 is improved. As a result, a thinner reflective layer 154 may be formed that still provides sufficient reflective properties and visible light transmission. Additionally, the reduced thickness of the reflective layer 154 allows for less material to be used in each panel that is manufactured, thus improving manufacturing throughput and efficiency, increasing the usable life of the target (e.g., silver) used to form the reflective layer 154, and reducing overall manufacturing costs.

Further, the seed layers 150 or 152 can provide a barrier between the metal oxide layer 140 and the reflective layer 154 to reduce the likelihood of any reaction of the material of the reflective layer 154 and the oxygen in the lower metal oxide layer 140, especially during subsequent heating processes. As a result, the resistivity of the reflective layer 154 may be reduced, thus increasing performance of the reflective layer 154 by lowering the emissivity.

Formed on the reflective layer 154 is a barrier layer 156, which can protect the reflective layer 154 from being oxidized. For example, the barrier layer can be a diffusion barrier, stopping oxygen from diffusing into the silver layer from the upper oxide layer 160. The barrier layer 156 can comprise titanium, nickel or a combination of nickel and titanium.

Formed on the barrier layer 156 is an upper oxide layer 160, which can function as an antireflective film stack, including a single layer or multiple layers for different functional purposes. The antireflective layer 160 serves to reduce the reflection of visible light, selected based on transmittance, index of refraction, adherence, chemical durability, and thermal stability. In some embodiments, the antireflective layer 160 comprises tin oxide, offering high thermal stability properties. The antireflective layer 160 can comprise titanium dioxide, silicon nitride, silicon dioxide, silicon oxynitride, niobium oxide, SiZrN, tin oxide, zinc oxide, or any other suitable dielectric material.

Formed on the antireflective layer 160 is an optical filler layer 170. The optical filler layer 170 can be used to provide a proper thickness to the low-e stack, for example, to provide an antireflective property. The optical filler layer preferably has high visible light transmittance. In some embodiments, the optical filler layer 170 is made of tin oxide and has a thickness of, for example, 100 Å. The optical filler layer may be used to tune the optical properties of the low-e panel 105. For example, the thickness and refractive index of the optical filler layer may be used to increase the layer thickness to a multiple of the incoming light wavelengths, effectively reducing the light reflectance and improving the light transmittance.

Formed on the optical filler layer 170 is an upper protective layer 180. An upper protective layer 180 can be used for protecting the total film stack, for example, to protect the panel from physical or chemical abrasion. The upper protective layer 180 can be an exterior protective layer, such as silicon nitride, silicon oxynitride, titanium oxide, tin oxide, zinc oxide, niobium oxide, or SiZrN.

In some embodiments, adhesion layers can be used to provide adhesion between layers. The adhesion layers can be made of a metal alloy, such as nickel-titanium, and have a thickness of, for example, 30 Å.

It should be noted that depending on the exact materials used, some of the layers of the low-e stack 190 may have some materials in common. An example of such a stack may use a zinc-based material in the oxide dielectric layers 140 and 160. As a result, a relatively low number of different targets can be used for the formation of the low-e stack 190.

In some embodiments, the coating can comprise a double or triple layer stack, having multiple IR reflective layers. In some embodiments, the layers can be formed using a plasma enhanced, or reactive sputtering, in which a carrier gas (e.g., argon) is used to eject ions from a target, which then pass through a mixture of the carrier gas and a reactive gas (e.g., oxygen), or plasma, before being deposited.

The coated transparent panels can comprise a glass substrate or any other transparent substrates, such as substrates made of organic polymers. The coated transparent panels can be used in window applications such as vehicle and building windows, skylights, or glass doors, either in monolithic glazings or multiple glazings with or without a plastic interlayer or a gas-filled sealed interspace.

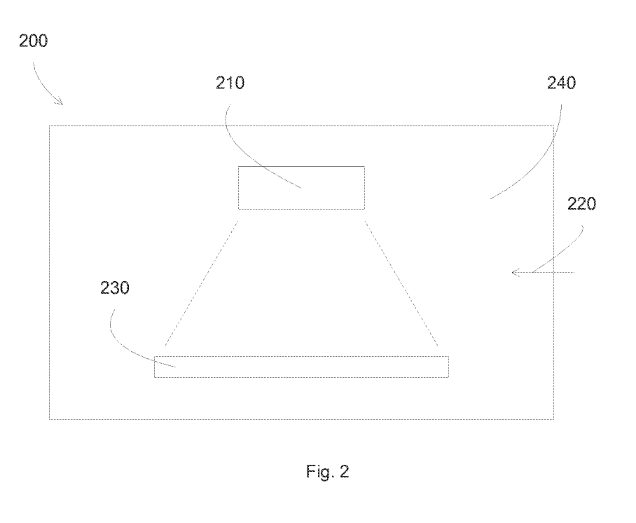

FIG. 2 illustrates exemplary physical vapor deposition (PVD) systems according to some embodiments of the present invention. The PVD system, also commonly called sputter system or sputter deposition system, 200 includes a housing that defines, or encloses, a processing chamber 240, a substrate 230, a target assembly 210, and reactive species delivered from an outside source 220. The substrate can be stationary, or in some manufacturing environments, the substrate may be in motion during the deposition processes. During deposition, the target is bombarded with argon ions, which releases sputtered particles toward the substrate 230. The sputter system 200 can perform blanket deposition on the substrate 230, forming a deposited layer that cover the whole substrate, e.g., the area of the substrate that can be reached by the sputtered particles generated from the target assembly 210.

The materials used in the target assembly 210 may, for example, include tin, zinc, magnesium, aluminum, lanthanum, yttrium, titanium, antimony, strontium, bismuth, silicon, silver, nickel, chromium, copper, gold, or any combination thereof (i.e., a single target may be made of an alloy of several metals). Additionally, the materials used in the targets may include oxygen, nitrogen, or a combination of oxygen and nitrogen in order to form the oxides, nitrides, and oxynitrides described above. Additionally, although only one target assembly 210 is shown, additional target assemblies may be used. As such, different combinations of targets may be used to form, for example, the dielectric layers described above. For example, in an embodiment in which the dielectric material is zinc-tin-titanium oxide, the zinc, the tin, and the titanium may be provided by separate zinc, tin, and titanium targets, or they may be provided by a single zinc-tin-titanium alloy target. For example, the target assembly 210 can comprise a silver target, and together with argon ions, sputter deposit a silver layer on substrate 230. The target assembly 210 can comprise a metal or metal alloy target, such as tin, zinc, or tin-zinc alloy, and together with reactive species of oxygen to sputter deposit a metal or metal alloy oxide layer.

The sputter deposition system 200 can comprise other components, such as a substrate support for supporting the substrate. The substrate support can comprise a vacuum chuck, electrostatic chuck, or other known mechanisms. The substrate support can be capable of rotating around an axis thereof that is perpendicular to the surface of the substrate. In addition, the substrate support may move in a vertical direction or in a planar direction. It should be appreciated that the rotation and movement in the vertical direction or planar direction may be achieved through known drive mechanisms which include magnetic drives, linear drives, worm screws, lead screws, a differentially pumped rotary feed through drive, etc.

In some embodiments, the substrate support includes an electrode which is connected to a power supply, for example, to provide a RF or dc bias to the substrate, or to provide a plasma environment in the process housing 240. The target assembly 210 can include an electrode which is connected to a power supply to generate a plasma in the process housing. The target assembly 210 is preferably oriented towards the substrate 230.

The sputter deposition system 200 can also comprise a power supply coupled to the target electrode. The power supply provides power to the electrodes, causing material to be, at least in some embodiments, sputtered from the target. During sputtering, inert gases, such as argon or krypton, may be introduced into the processing chamber 240 through the gas inlet 220. In embodiments in which reactive sputtering is used, reactive gases may also be introduced, such as oxygen and/or nitrogen, which interact with particles ejected from the targets to form oxides, nitrides, and/or oxynitrides on the substrate.

The sputter deposition system 200 can also comprise a control system (not shown) having, for example, a processor and a memory, which is in operable communication with the other components and configured to control the operation thereof in order to perform the methods described herein.

In some embodiments, the present invention discloses methods to form low-e panels, comprising forming a first seed layer for a second seed layer, wherein the second seed layer can be used as a seed layer for an infrared reflective layer. In some embodiments, a transparent substrate is provided. A first seed layer is formed over the transparent substrate. The first seed layer comprises a metallic element having hexagonal dose packing (hcp) and face center cubic (fcc) (111) structure. A second seed layer is formed over the first seed layer. The second seed layer comprises zinc oxide or doped zinc oxide material. The second seed layer preferably comprises (002) crystal orientation. For example, more than about 30% of the second seed layer has a (002) crystallographic orientation. A silver layer is formed on the second seed layer. The silver layer preferably comprises (111) crystal orientation.

In some embodiments, the first seed layer can improve the crystallinity and (002) orientation of the zinc oxide or doped zinc oxide layer. The improvement of the zinc oxide or doped zinc oxide layer can in turn improve the (111) silver growing on top of the zinc oxide or doped zinc oxide layer, producing a silver layer with improved electrical conductivity. The present methods thus can maximize volume production, throughput, and efficiency of the manufacturing process used to form low emissivity panels.

In some embodiments, the present invention discloses an improved coated transparent panel, such as a coated glass, that has high visible light transmission and IR reflection. The present invention also discloses methods of producing the improved, coated, transparent panels, which comprise specific layers in a coating stack.

In some embodiments, the present invention discloses forming an underlayer layer comprising a metallic element before forming a zinc oxide layer. The underlayer can serve as a template, e.g., a seed layer, for the formation of the zinc oxide layer. For example, metallic elements have strong tendency to crystallize at low temperature, even on amorphous substrates, thus a seed layer containing metallic elements can have a preferred crystal orientation, which can serve to promote forming a zinc oxide layer with a desired crystalline structure. Thus, in some embodiments, metallic seed layers having metals possessing hexagonal close packing (hcp) and face center cubic (fcc) (111) structure can induce pseudo-epitaxial growth of basal plane (002) of zinc oxide on top of the metallic seed layer. In the present description, the term “zinc oxide layer” means “a layer comprising zinc oxide material”, thus includes zinc oxide layers and doped zinc oxide layers.

In some embodiments, the seed layer preferably comprises a pure metal layer, such as Ti, Zr, Hf, Y, La, Zn, Co, Ru, Cr, Mo, W, V, Nb, Ta, and rare earth metals. In some embodiments, the seed layer comprises mixtures or compounds of metallic elements, such as metal alloys, metal nitrides, or metal oxynitride.

In some embodiments, the seed layer is preferably oxidizable, but not reacting with the substrate, for example to improve or enhance the adhesion of zinc oxide to the glass substrate. The seed layer further preferably comprises metal elements that form transparent metal oxides having high refractive index, which can further enhance optical properties in low emissivity glass applications. The oxidation process can occur separately, or can occur during the fabrication of the products, such as a subsequent thermal treatment of glass tempering process, or during the deposition of zinc oxide.

In some embodiments, a portion of the metal seed layer remains in place and retains its metallic composition after the zinc oxide layer is formed. In some embodiments, the metal seed layer can be oxidized, for example, during the formation of the zinc oxide or during a subsequent annealing process.

In some embodiments, the present invention discloses an in-situ formation of a zinc oxide layer on a seed layer without exposure to atmosphere. By controlling the surface of the seed layer, for example, to reduce any possible surface contamination, the crystallization of zinc oxide layer can be further promoted and not impeded by any adhered particulates.

In some embodiments, the present seed layer can provide improved zinc oxide layer with thinner film thickness. The crystallization of zinc oxide layer, and consequently its electrical conductivity, is not a function of film thickness, and thus can offer similar film quality at different thicknesses. The thickness of zinc oxide layer can be less 100 nm, and preferably less than 50 nm. The seed layer can also be thin, preferably less than 10 nm.

In some embodiments, the present invention discloses methods to form seed layer and zinc oxide layer, comprising thin film deposition methods such as physical vapor deposition (MID), chemical vapor deposition (CVD), atomic layer deposition (ALD), or wet chemical deposition methods such as electroplating or electroless deposition.

In some embodiments, the present invention discloses sputter systems, and methods to operate the sputter systems, for making coated panels having a first seed layer serving as a template for a second ZnO seed layer, which then serves as a template for a silver layer. In some embodiments, the present invention discloses an in-line deposition system, comprising a transport mechanism for moving substrates between deposition stations.

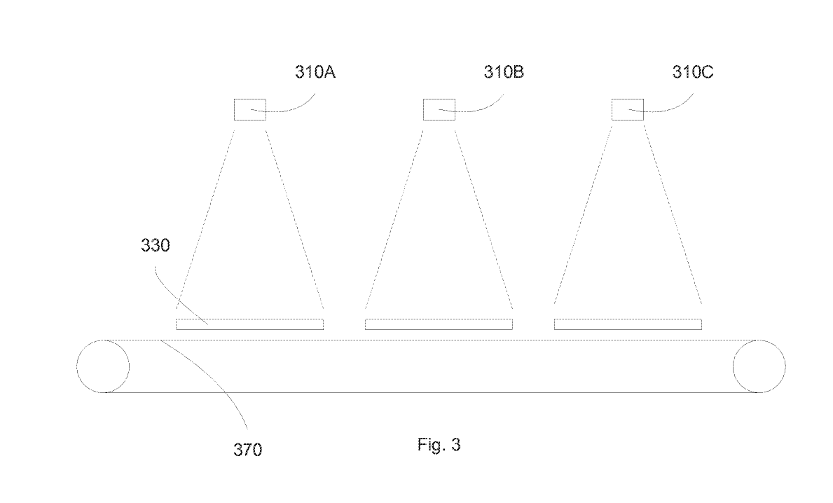

FIG. 3 illustrates an exemplary in-line deposition system according to some embodiments of the present invention. A transport mechanism 370, such as a conveyor belt or a plurality of rollers, can transfer substrate 330 between different sputter deposition stations. For example, the substrate can be positioned at station #1, comprising a target assembly 310A, then transferred to station #2, comprising target assembly 310B, and then transferred to station #3, comprising target assembly 310C. Station #1 can be configured to deposited a first seed layer, for example, comprising a metallic element having hcp or fcc structure. Station #2 can be configured to deposited a zinc oxide or a doped zinc oxide layer, which can comprise (002) crystal orientation. Station #3 can be configured to deposit a silver layer, which can comprise (111) crystal orientation. Other configurations can be included, for example, station #2 can comprise multiple target assemblies for co-sputtering. In addition, other stations can be included, such as input and output stations, or anneal stations.

After depositing a first layer in station #1, for example, a metal seed layer having hcp or fcc structure for promoting (002) orientation in a zinc oxide layer, the substrate is moved to station #2, where a zinc oxide (or doped zinc oxide) layer can be deposited. The (002) crystal orientation of the deposited zinc oxide layer can be improved by the presence of the metal seed underlayer. The substrate is then transferred to station #3 to deposit a silver layer over the zinc oxide layer. The (111) crystal orientation of the silver layer can be improved by the improved (002) orientation of the zinc oxide underlayer.

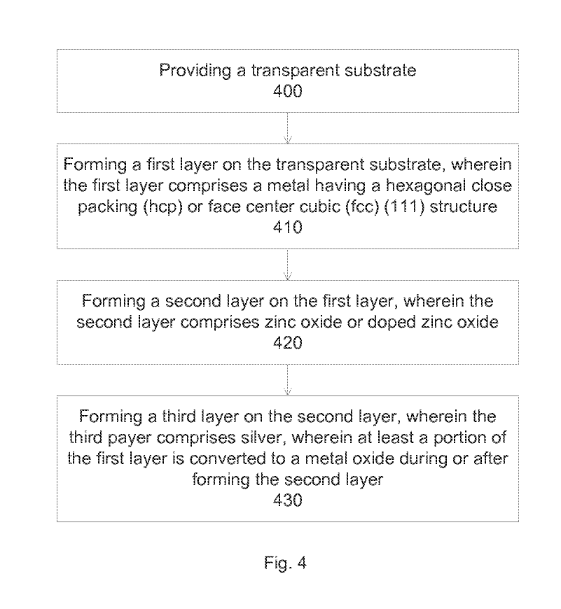

FIG. 4 illustrates an exemplary flow chart for seed layer deposition according to some embodiments of the present invention. In operation 400, a transparent substrate is provided. In operation 410, a first layer is formed on the transparent substrate. In some embodiments, the first layer comprises a metal having a hexagonal dose packing (hcp) or face center cubic (fcc) (111) structure. The first layer can comprise a material that can easily crystallize on a substrate, e.g., materials that crystallize at low temperatures such as below about 100 C, or at or below room temperature. For example, elemental metals and their simple binary alloys can form crystal structure on any substrate, including on the amorphous silicate glass at room temperature. In some embodiments, the first layer comprises a crystalline layer or polycrystalline layer. Using materials having low crystallization temperature, the first layer can comprise a crystallized layer by sputtering at low temperatures, such as below about 100 C or at or below room temperature of about 25 C. The crystallized first layer can serve as a template for promoting a crystal orientation of a subsequent deposited layer.

In some embodiments, the first layer is preferably thin, for example, less than or equal to about 10 nm. The first layer can comprise a metallic element having hcp or fcc structure for promoting a (002) crystal orientation of a subsequently deposited zinc oxide-containing layer. For example, the metallic element can be Ti, Zr, Hf, Zn, Co, Ru, Y, La, or most rare earth metals, which can promote ZnO (002) growth, for example, by pseudo-epitaxial growth due to the crystal structure matching between these metals and the Wurtzite structure of ZnO. The first layer can comprise a pure metal layer, or a binary metal alloy layer.

In some embodiments, some portion of the first layer is converted to an oxide layer, for example, during or after the formation of the subsequent layer or during an additional annealing step. The partial oxidation of the metallic element in the first layer can produce strong bonding to the surrounding layers, such as bonding to the silicate glass substrate or to the subsequently deposited zinc oxide. The enhanced bonding can improve the integrity and the durability of the resulting layer structure.

In some embodiments, the first layer comprises the metallic element of Ti, Zr or Hf, which can form oxides having high refractive index that can further improve the optical property of the layer structure.

In operation 420, a second layer is formed on the first layer. In some embodiments, the second layer comprises zinc oxide, e.g., a zinc oxide containing layer such as a zinc oxide layer or a doped zinc oxide layer. Since the second layer is deposited on the first layer, the crystal orientation of the first layer can influence the crystal orientation of the second layer, thus the first layer can enable a zinc oxide layer having improved (002) crystal orientation, as compared to a zinc oxide layer without the first layer.

In some embodiments, the second layer is formed on the first layer without being exposed to the ambient environment, e.g., ambient air. The control of the sequence deposition of the first and second layers can enhance the templating effect of the first layer on the second layer, improving the crystallinity of the second layer. In some embodiments, the second layer is less than or equal to about 100 nm. In some embodiments, the second layer is less than or equal to about 10 nm.

In operation 430, a third layer is deposited on the second layer. In some embodiments, the third layer comprises silver. Since the third layer is deposited on the second layer, the crystal orientation of the second layer can influence the crystal orientation of the third layer, thus the second zinc oxide layer having improved (002) crystal orientation can enable a silver layer having improved (111) crystal orientation, as compared to a silver layer deposited on a zinc oxide layer with less (002) crystal orientation.

In some embodiments, an annealing step can be performed in an oxygen-containing ambient, for example, after forming the second layer. The annealing step can partially oxidize the first layer, forming an at least partially oxidized first layer.

In some embodiments, a photovoltaic device, a LED (light emitting diode) device, a LCD (liquid crystal display) structure, or an electrochromic layer is formed on the substrate having the layer structure.

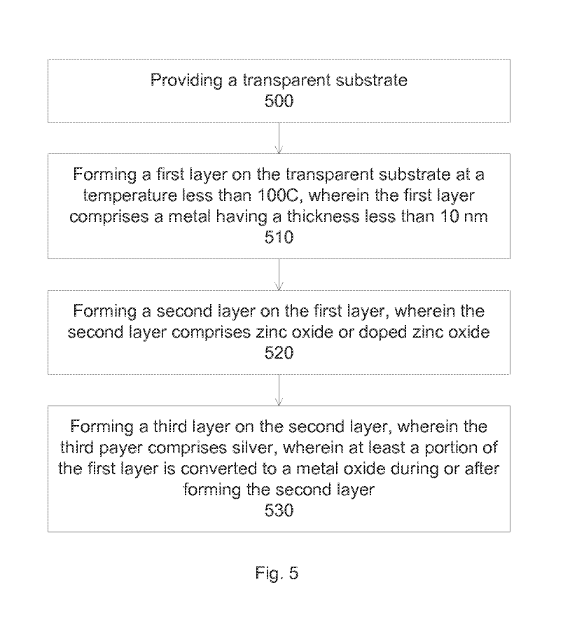

FIG. 5 illustrates another exemplary flow chart for seed layer deposition according to some embodiments of the present invention. In operation 500, a transparent substrate is provided. In operation 510, a first layer is formed on the transparent substrate at a temperature less than 100 C, wherein the first layer comprises a metal having a thickness less than 10 nm. In operation 520, a second layer is formed on the first layer, wherein the second layer comprises zinc oxide or doped zinc oxide. In operation 530, a third layer is formed on the second layer, wherein the third layer comprises silver, wherein at least a portion of the first layer is converted to a metal oxide during or after forming the second layer.

Although the foregoing examples have been described in some detail for purposes of clarity of understanding, the invention is not limited to the details provided. There are many alternative ways of implementing the invention. The disclosed examples are illustrative and not restrictive.

What is claimed is:

1. A method for forming an article comprising:
providing a transparent substrate;
forming a first layer on the transparent substrate, wherein the first layer comprises a metal having a hexagonal dose packing (hcp) or face center cubic (fcc) (111) structure;
forming a second layer on the first layer, wherein the second layer comprises zinc oxide or doped zinc oxide;
forming a third layer on the second layer, wherein the third payer comprises silver;
wherein at least a portion of the first layer is converted to a metal oxide during or after forming the second layer.

2. The method of claim 1 wherein the transparent substrate comprises a glass substrate.

3. The method of claim 1 wherein the second layer is formed in-situ on the first layer without exposing to ambient environment.

4. The method of claim 1 wherein second layer comprises (002) crystal orientation.

5. The method of claim 1 wherein the first layer is formed at a temperature less than 100 C.

6. The method of claim 1 wherein the first layer comprises a metal layer.

7. The method of claim 6 wherein the metal is selected from a group consisting of Ti, Zr, Hf, and rare earth metals.

8. The method of claim 1 wherein the thickness of the first layer is less than 10 nm.

9. The method of claim 1 wherein the thickness of the second layer is less than 100 nm.

10. The method of claim 1 further comprising
annealing in an oxygen-containing ambient after forming the second layer.

11. The method of claim 1 further comprising
forming a photovoltaic device on the substrate.

12. The method of claim 1 further comprising
forming a LED device on the substrate.

13. The method of claim 1 further comprising
forming a LCD display on the substrate.

14. The method of claim 1 further comprising
forming an electrochromic layer on the substrate.

15. A method for forming a coated article comprising:
providing a transparent substrate;
forming a first layer on the transparent substrate at a temperature less than 100 C, wherein the first layer comprises a metal having a thickness less than 10 nm;
forming a second layer on the first layer, wherein the second layer comprises zinc oxide or doped zinc oxide;
forming a third layer on the second layer, wherein the third layer comprises silver;
wherein at least a portion of the first layer is converted to a metal oxide during or after forming the second layer.

16. The method of claim 15 wherein the second layer is formed in-situ on the first layer without exposing to ambient environment.

17. The method of claim 15 wherein second layer comprises (002) crystal orientation.

18. The method of claim 15 wherein the first layer comprises a metal layer.

19. The method of claim 18 wherein the metal is selected from a group consisting of Ti, Zr, Hf, and rare earth metals.

20. The method of claim 15 further comprising
annealing in an oxygen-containing ambient after forming the second layer.
